(19) United States
(12) Patent Application Publication
(10) Pub. No.: US 2014/0027156 A1
(43) Pub. Date: Jan. 30, 2014

(54) MULTILAYER TYPE CORELESS SUBSTRATE AND METHOD OF MANUFACTURING THE SAME

(71) Applicant: SAMSUNG ELECTRO-MECHANICS CO., LTD, Gyunggi-do (KR)

(72) Inventors: Ki Hwan Kim, Gyunggi-do (KR); Myung Sam Kang, Gyunggi-do (KR); Keung Jin Sohn, Gyunggi-do (KR); Yoong Oh, Gyunggi-do (KR); Da Hee Kim, Gyunggi-do (KR); Ki Young Yoo, Gyunggi-do (KR); Han Ui Lee, Gyunggi-do (KR); Sang Hyuck Oh, Gyunggi-do (KR)

(73) Assignee: Samsung Electro-Mechanics Co., Ltd, Gyunggi-do (KR)

(21) Appl. No.: 13/664,091

(22) Filed: Oct. 30, 2012

(30) Foreign Application Priority Data
Jul. 26, 2012 (KR) 10-2012-0081912

(51) Int. Cl. H05K 3/46; H05K 3/14; H05K 3/10; H05K 3/40; H05K 1/11; H05K 1/09

(52) U.S. Cl. 174/251; 174/262; 29/846; 29/847

(57) ABSTRACT

Disclosed herein is a method of manufacturing a multilayer type coreless substrate, the method including: (A) preparing a carrier substrate including at least one copper foil formed on one surface or both surfaces of an insulating surface; (B) forming a coreless printed circuit precursor on one surface or both surfaces of the carrier substrate; (C) separating the carrier substrate; (D) performing a polishing cutting process on the coreless printed circuit precursor; and (E) laminating a plurality of other insulating layers on a flat outer surface of the coreless printed circuit precursor, the plurality of other insulating layers sequentially including other circuit layers and other pillars.

### CROSS REFERENCE TO RELATED APPLICATION

This application claims the benefit of Korean Patent Application No. 10-2012-0081912, filed on Jul. 26, 2012, entitled “Multi-layer Type Coreless Substrate and Method of Manufacturing the Same”, which is hereby incorporated by reference in its entirety into this application.

### BACKGROUND OF THE INVENTION

1. Technical Field

The present invention relates to a multilayer type coreless substrate and a method of manufacturing the same.

2. Description of the Related Art

Generally, a printed circuit board is implemented by wiring a copper foil on one surface or both surfaces of a board made of various kinds of thermosetting synthetic resins, fixedly disposing integrated circuits (ICs) or electronic components on the board, and implementing electrical wirings therebetween and then coating the electrical wirings with an insulator.

In accordance with the recent development of electronic industries, a demand for multi-functional and light and small electronic components has been rapidly increased. Therefore, there is a need to increase a wiring density of a printed circuit board on which the electronic components are mounted and reduce a thickness thereof.

In particular, in order to cope with the thinness of the printed circuit board, a coreless substrate with the reduced thickness and signal processing time by removing a core substrate has been spotlighted. In case of the coreless substrate, since the core substrate is removed, a carrier member serving as a support during a manufacturing process is required. Buildup layers including circuit layers and insulating layers are formed on both surfaces of the carrier member by a general method of manufacturing a substrate and the carrier member is removed to separate upper and lower substrates from each other, such that the coreless substrate is completed.

As described in Korean Patent Laid-Open Publication No. 2010-0043547 (published on Apr. 29, 2010), in a method of manufacturing a coreless substrate according to the prior art, a laser direct ablation (LDA) method has been performed in order to form opening parts in an insulating layer before forming vias for electrical connection between the respective buildup layers.

However, the LDA method has caused an increase in machining time due to a limitation of a laser spot size when a size of the opening part is large.

Further, in the method of manufacturing a coreless substrate according to the prior art, since laser machining should be performed several times, a process was complicated and a cost has increased.

### SUMMARY OF THE INVENTION

The present invention has been made in an effort to provide a multilayer type coreless substrate in which a plurality of insulating layers including pillars for electrical connection formed by a patterning process using a dry film are laminated.

Further, the present invention has been made in an effort to provide a method of manufacturing a multilayer type coreless substrate in which a plurality of insulating layers including pillars for electrical connection are laminated.

According to a preferred embodiment of the present invention, there is provided a multilayer type coreless substrate including: a first insulating layer including at least one first pillar; a plurality of insulating layers each laminated in directions of both surfaces of the first insulating layer and each including at least one circuit layer and at least one other pillar connected to the circuit layer; and a plurality of outermost circuit layers each contacting pillars included in outermost insulating layers among the plurality of insulating layers and disposed on outer surfaces of the outermost insulating layers, wherein the circuit layers and other pillars formed on the directions of both surfaces of the first insulating layer, respectively, are disposed symmetrically to each other based on the first insulating layer.

The circuit layers and other pillars may be sequentially laminated in directions of both surfaces based on the first pillar of the first insulating layer, respectively, and may be disposed symmetrically to each other based on the first pillar.

The outermost circuit layer may include a first or second surface treating film formed thereon.

The first surface treating film may be any one of an organic solderability preservative (OSP) treating film, a black oxide film, and a brown oxide film, instead of a solder resist (SR).

The second surface treating film may be any one of a gold plating film, an electro gold plating film, an electroless gold plating film, and an electroless nickel immersion gold (ENIG) plating film.

According to another preferred embodiment of the present invention, there is provided a method of manufacturing a multilayer type coreless substrate, the method including: (A) preparing a carrier substrate including at least one copper foil formed on one surface or both surfaces of an insulating surface; (B) forming a coreless printed circuit precursor on one surface or both surfaces of the carrier substrate; (C) separating the carrier substrate; (D) performing a polishing cutting process on the coreless printed circuit precursor; and (E) laminating a plurality of other insulating layers on an outer surface of the coreless printed circuit precursor, the plurality of other insulating layers sequentially including other circuit layers and other pillars.

The method may further include: (F) forming outermost circuit layers at outermost insulating layers among other insulating layers; and (G) forming a first or second surface treating film on the outermost circuit layers.

The first surface treating film may be any one of an OSP treating film, a black oxide film, and a brown oxide film, instead of an SR, and the second surface treating film may be any one of a gold plating film, an electro gold plating film, an electroless gold plating film, and an ENIG plating film.

Step (B) may include: (B-1) forming a plurality of first pillars by filling a first dry film pattern disposed on one surface or both surfaces of the carrier substrate with copper; (B-2) delaminating the first dry film pattern; (B-3) forming a first insulating layer on one surface or both surfaces of the carrier substrate so as to bury the first pillars therein; (B-4) performing a polishing cutting process on the first insulating layer so as to expose the first pillars; (B-5) forming a dry film pattern for forming a first circuit layer on an outer surface of the first insulating layer exposing the first pillars; (B-6) forming the first circuit layer by filling the dry film pattern for forming the first circuit layer with copper and delaminating the dry film pattern for forming the first circuit layer; (B-7) forming a second dry film pattern on the outer surface of the first insulating layer including the first circuit layer; (B-8) forming second pillars connected to the first circuit layer by filling the second dry film pattern with copper and delaminating the second dry film pattern; and (B-9) forming a second insulating layer so as to bury the second pillars therein.

Steps (B-1), (B-6), and (B-8), the copper may be filled by any one of a chemical vapor deposition (CVD) method, a physical vapor deposition (PVD) method, a subtractive method, an additive method using electroless copper plating or electro copper plating, a semi-additive process (SAP), and a modified semi-additive process (MSAP).

In steps (B-1), (B-6), and (B-8), the copper may be filled by a sputtering method.

In step (C), the carrier substrate may include an insulating plate; at least two copper foils laminated on one surface or both surfaces of the insulating plate; and a release layer disposed between the copper foils and may be routed and separated using the release layer.

Step (D) may be performed by using any one of a belt-sander, an end-mill, or a ceramic buff, and a chemical mechanical polishing (CMP) process.

Step (E) may include: (E-1) forming other circuit layers on the flat outer surface; (E-2) forming dry film patterns for forming other pillars on the flat outer surface including other circuit layers formed thereon; (E-3) forming other pillars connected to other circuit layers by filling the dry film patterns for forming other pillars with copper; (E-4) delaminating the dry film patterns for forming other pillars; (E-5) laminating other insulating layers so as to bury other pillars; and (E-6) polishing and cutting other insulating layers so as to expose other pillars, and steps (E-1) to (E-6) may be repeatedly performed.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a multilayer type coreless substrate according to a first preferred embodiment of the present invention;

FIGS. 2A to 2L are process views sequentially showing a method of manufacturing a multilayer type coreless substrate according to the first preferred embodiment of the present invention; and

FIGS. 3A to 3D are process views sequentially showing a method of manufacturing a multilayer type coreless substrate according to a second preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

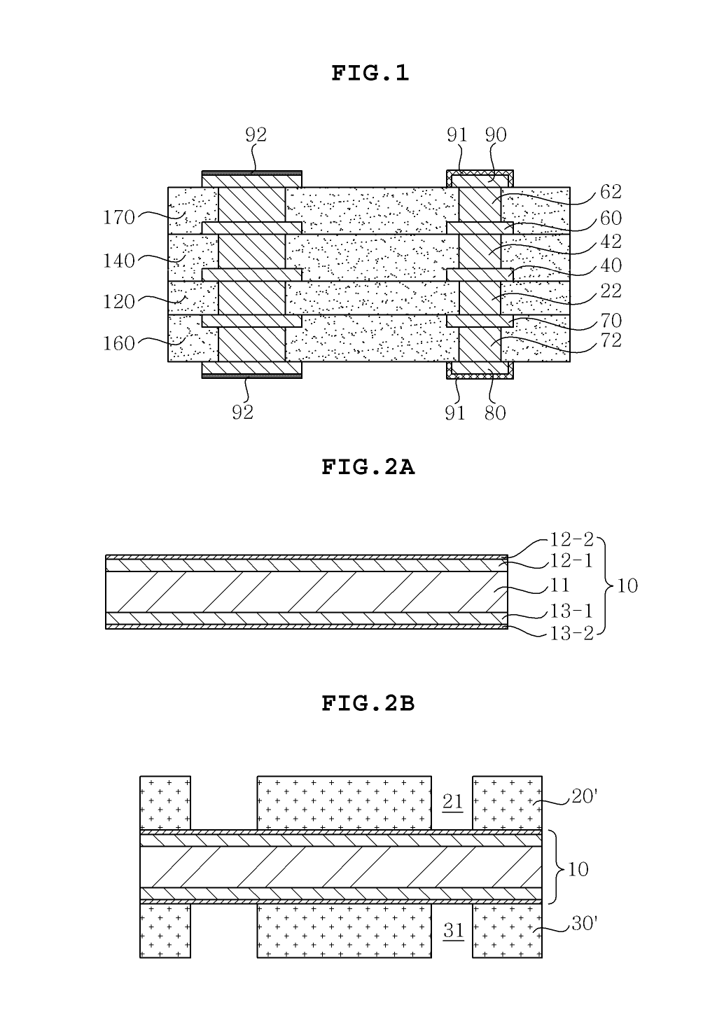

FIG. 1 is a cross-sectional view of a multilayer type coreless substrate according to a first preferred embodiment of the present invention. Here, an example in which the multilayer type coreless substrate according to the first preferred embodiment of the present invention includes four insulating layers and five circuit layers will be described. Further, a multilayer type coreless substrate including five or more circuit layers may be used.

The multilayer type coreless substrate according to the first preferred embodiment of the present invention is configured to include a first insulating layer 120, an upper second insulating layer 140, an upper third insulating layer 170, a lower second insulating layer 160, and an upper first circuit layer 40 and an upper second circuit layer 60 each provided symmetrically to a lower third circuit layer 70 and a bottom circuit layer 80 while facing the lower third circuit layer 70 and the bottom circuit layer 80 based on the first insulating layer 120.

The multilayer type coreless substrate according to the first preferred embodiment of the present invention as described above includes a plurality of pillars 72, 22, 42, and 62 electrically connecting the respective circuit layers to each other from the bottom circuit layer 80 up to a top circuit layer 90 and a first surface treating film 91 formed instead of a solder resist (SR) so as to cover the bottom circuit layer 80 or the top circuit layer 90 in order to prevent oxidation of the bottom circuit layer 80 or the top circuit layer 90 and improve soldering of the bottom circuit layer 80 or the top circuit layer 90.

Further, the multilayer type coreless substrate according to the first preferred embodiment of the present invention may further include a second surface treating film 92 formed on a portion of the bottom circuit layer 80 or a portion of the top circuit layer 90 using a metal material having high electrical conductivity in order to increase electrical conductivity of the bottom circuit layer 80 or the top circuit layer 90 to improve reliability of connection between the bottom circuit layer 80 or the top circuit layer 90 and external elements.

Therefore, the multilayer type coreless substrate according to the first preferred embodiment of the present invention may include at least one insulating layer such as the first insulating layer 120 including only a first pillar 22 without a circuit layer. The first insulating layer 120 as described above serves as a core, such that a plurality of circuit layers and pillars may be provided symmetrically to each other based on the first insulating layer 120 in a vertical direction.

More specifically, the plurality of circuit layers 40, 60, 70, 80, and 90 or the plurality of pillars 22, 42, 62, and 72 may be formed using a dry film pattern by a method such as a chemical vapor deposition (CVD) method, a physical vapor deposition (PVD) method such as a sputtering method, a subtractive method, an additive method using electroless copper plating or electro copper plating, a semi-additive process (SAP), a modified semi-additive process (MSAP), or the like.

The first surface treating film 91 may be any one of an organic solderability preservative (OSP) treating film, a black oxide film, and a brown oxide film. Particularly, the OSP treating film is divided into an organic solvent type OSP treating film and a water soluble type OSP treating film, wherein the organic solvent type OSP treating film may be formed on a surface of the bottom circuit layer 80 or top circuit layer 90 by a roll coating method, a spray coating method, or the like, and the water soluble type OSP treating film may be formed by a dipping method.

In addition, the second surface treating film 92 may be a film made of a metal material having high electrical conductivity, for example, a gold plating film, an electro gold plating film, an electroless gold plating film, or an electroless nickel immersion gold (ENIG) plating film.

Particularly, the ENIG plating film may be formed by plating nickel by an electroless plating process and then plating immersion gold and has advantages such as excellent heat resistance and excellent solderability.

These first and second surface treating films 91 and 92 are not limited to the above-mentioned example, but may be a hot air solder leveling (HASL) film or all other plating films.

With the multilayer type coreless substrate according to the first preferred embodiment of the present invention as described above, a structure in which a plurality of insulating layers are laminated and a plurality of pillars for electrical connection between the laminated insulating layers may be easily implemented using a carrier substrate and a dry film.

Therefore, the pillars for electrical connection are easily formed instead of the vias formed using laser in the prior art. As a result, with the multilayer type coreless substrate according to the first preferred embodiment of the present invention, a manufacturing cost may be reduced and integration of circuits may be improved.

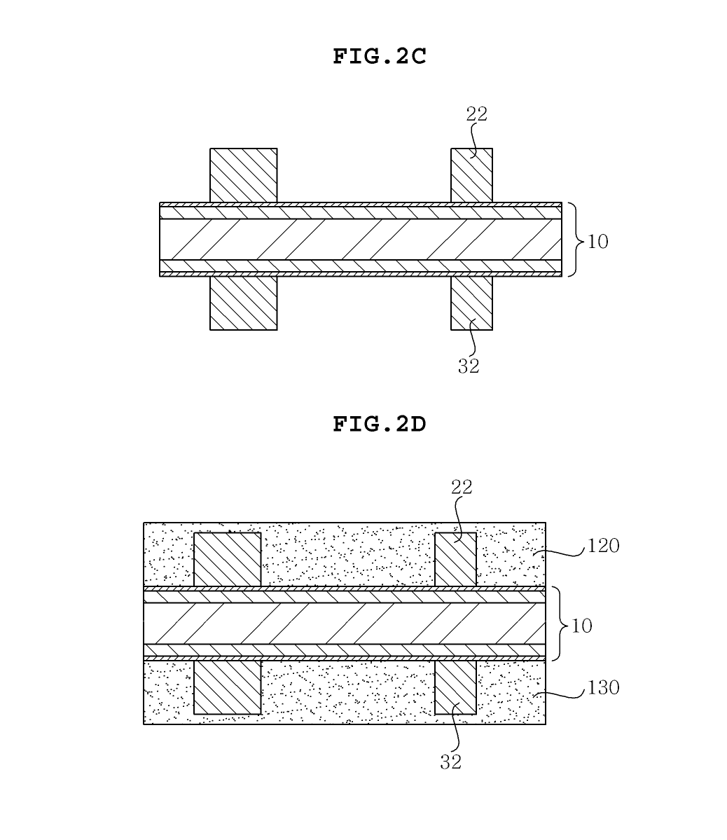

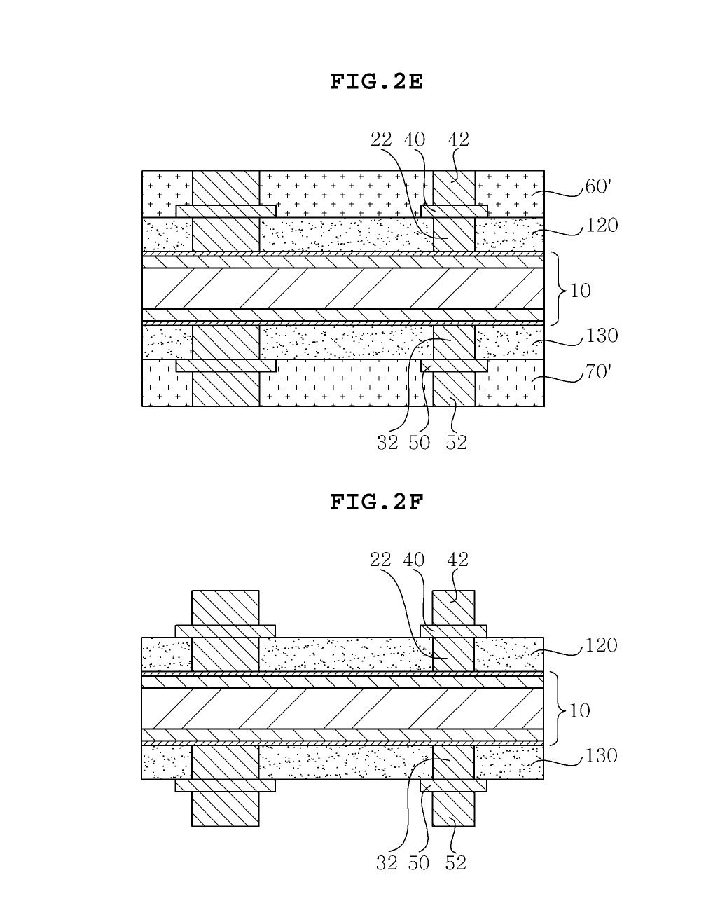

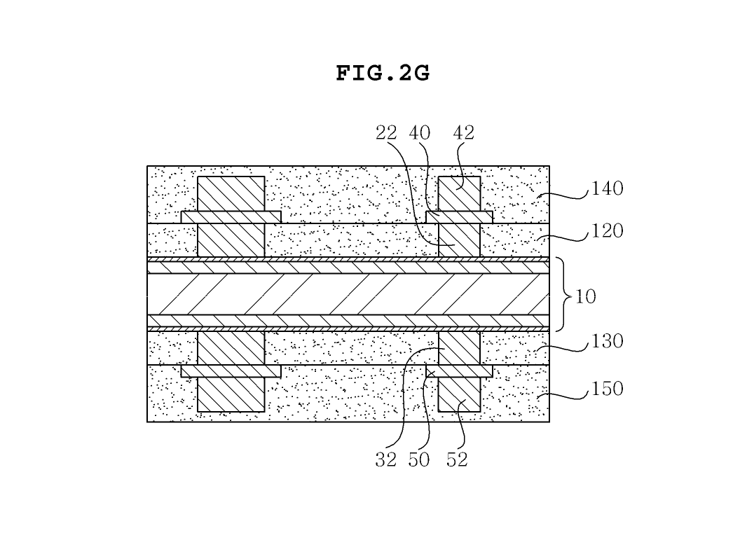

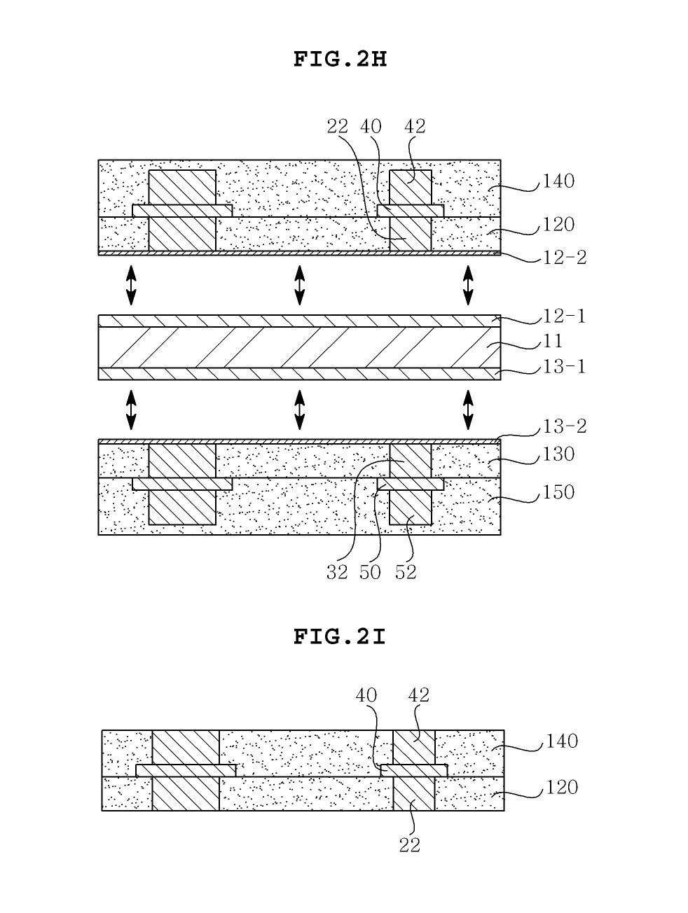

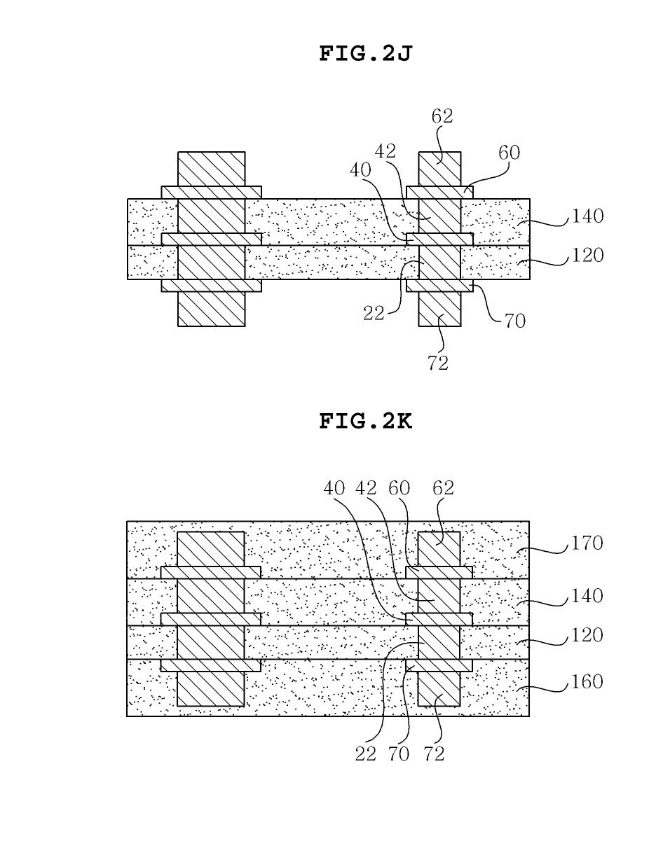

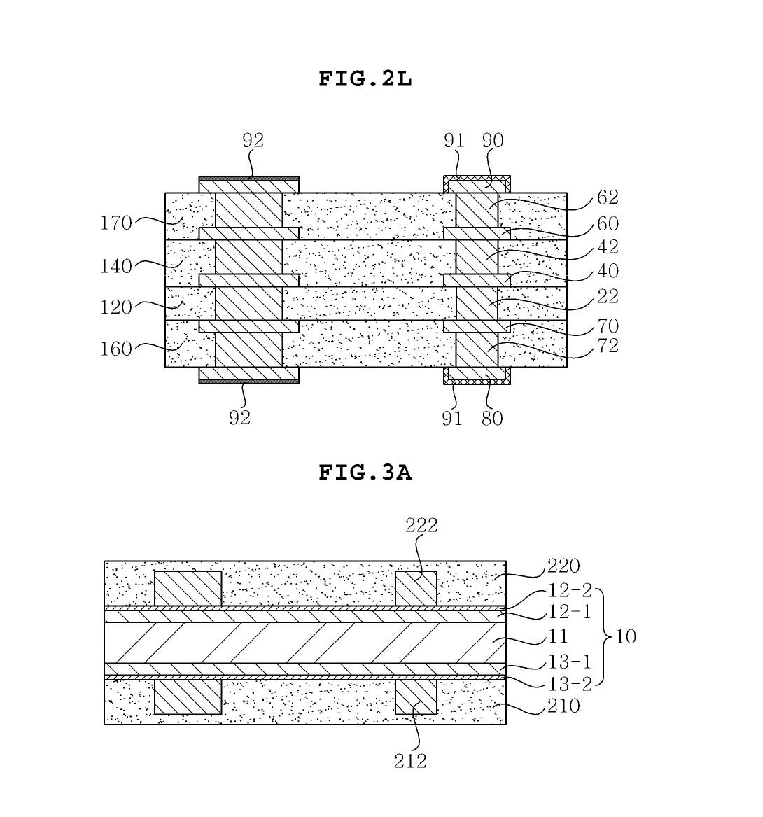

Hereinafter, a method of manufacturing a multilayer type coreless substrate according to the first preferred embodiment of the present invention will be described with reference to FIGS. 2A to 2L. FIGS. 2A to 2L are process views sequentially showing a method of manufacturing a multilayer type coreless substrate according to the first preferred embodiment of the present invention.

In the method of manufacturing a multilayer type coreless substrate according to the first preferred embodiment of the present invention, a carrier substrate 10 is first prepared, as shown in FIG. 2A.

The carrier substrate 10 has, for example, a structure in which two copper foils are laminated on one surface or both surfaces of an insulating plate 11 and serves to support the coreless substrate during a manufacturing process of the coreless substrate. Although the first preferred embodiment of the present invention describes that the carrier substrate 10 has a structure in which two copper foils are disposed on both surfaces of the insulating plate 11, the present invention is not limited thereto. That is, two or more copper foils may each be disposed on both surfaces of the insulating plate 11 while having a thickness difference therebetween.

More specifically, the insulating plate 11 of the carrier substrate 10 is made of a resin material, for example, a thermosetting resin such as an epoxy resin, a thermoplastic resin such as polyimide, or prepreg in which a reinforcing material such as glass fiber or inorganic filler is impregnated in the above-mentioned resin.

In relation to the insulating plate 11, a first upper copper foil 12-1 and a second upper copper foil 12-2 are disposed on an upper surface of the insulating plate 11 and a first lower copper foil 13-1 and a second lower copper foil 13-2 are disposed on a lower surface of the insulating plate 11.

Optionally, a release layer is disposed between the first upper copper foil 12-1 and the second upper copper foil 12-2 or between the first lower copper foil 13-1 and the second lower copper foil 13-2, thereby making it possible to easily separate the carrier substrate 10 in the subsequent process.

For example, the release layer is made of an adhesion material of a polymer material selected from a group consisting of borons, silicons, polyethylene terephthalate, polymethylpentene, and a combination thereof, but is not particularly limited thereto.

After the carrier substrate 10 as described above is prepared, first dry film patterns 20′ and 30′ having a plurality of opening parts 21 and 31 are formed on both surfaces of the carrier substrate 10, as shown in FIG. 2B.

More specifically, describing a process of forming the first dry film patterns 20′ and 30′, dry films are laminated on both surfaces of the carrier substrate 10 using a laminator.

Then, the dry films are selectively hardened through an exposing process of exposing the dry film to light and only portions of the dry films that are not hardened are dissolved using a developing solution, such that the dry films may be patterned as a first upper dry film pattern 20′ having an upper opening part 21 and a first lower dry film pattern 30′ having a lower opening part 31, as shown in FIG. 2B.

After the first dry film patterns 20′ and 30′ having the plurality of opening parts 21 and 31 are formed, a first pillar 22 and a first dummy pillar 32 are formed by filling the upper opening part 21 and the lower opening part 31 with copper by a method such as a CVD method, a PVD method such as a sputtering method, a subtractive method, an additive method using electroless copper plating or electro copper plating, an SAP, an MSAP, or the like.

Next, the first dry film patterns 20′ and 30′ are removed through delamination by a delamination solution to form a plurality of first pillars 22 and a plurality of first dummy pillars 32 on upper and lower surfaces of the carrier substrate 10, as shown in FIG. 2C. Here, the delamination solution for removing the first dry film patterns 20′ and 30′ may include alkali metal hydroxide, or the like.

After the plurality of first pillars 22 and the plurality of first dummy pillars 32 are formed on the upper and lower surfaces of the carrier substrate 10, a first insulating layer 120 and a first dummy insulating layer 130 each burying the plurality of first pillars 22 and the plurality of first dummy pillars 32 therein are formed, as shown in FIG. 2D.

The first insulating layer 120 and the first dummy insulating layer 130 may be formed by compressing insulating films in a form of an unhardened film to the first pillars 22 and the first dummy pillars 32 using, for example, a laminator.

In this case, in order to prevent damage during a compression process, the first insulating layer 120 and the first dummy insulating layer 130 may be formed to have thicknesses thicker than heights of the first pillar 22 and the first dummy pillar 32, respectively.

Thereafter, a polishing cutting process is performed on each of the first insulating layer 120 and the first dummy insulating layer 130 to expose each surface of the first pillar 22 and the first dummy pillar 32.

Here, the polishing cutting process of each of the first insulating layer 120 and the first dummy insulating layer 130 may be performed using a belt-sander, an end-mill, or a ceramic buff or be performed by a chemical mechanical polishing (CMP) process, or the like.

When each surface of the first pillar 22 and the first dummy pillar 32 is exposed through the polishing cutting process as described above, outer surfaces of the first insulating layer 120 and the first dummy insulating layer 130 may be planarized.

After each surface of the first pillar 22 and the first dummy pillar 32 is exposed, a first circuit layer 40 and a first dummy circuit layer 50 are formed on the exposed first pillar 22 and first dummy pillar 32, respectively.

The process of forming the first circuit layer 40 and the first dummy circuit layer 50 may be performed by filling a dry film pattern with copper by any one of methods such as a CVD method, a PVD method such as a sputtering method, a subtractive method, an additive method using electroless copper plating or electro copper plating, an SAP, an MSAP, and the like, similar to the process of forming the first pillar 22 and the first dummy pillar 32.

Then, as shown in FIG. 2E, a second upper dry film pattern 60′ and a second lower dry film pattern 70′ are formed on an upper surface of the first insulating layer 120 on which the first circuit layer 40 is disposed and a lower surface of the first dummy insulating layer 130 on which the first dummy circuit layer 50 is disposed, respectively.

Here, the second upper dry film pattern 60′ and the second lower dry film pattern 70′ may include a plurality of opening parts for forming second pillars 42 and second dummy pillars 52, respectively.

The second pillars 42 and the second dummy pillars 52 are formed by filling the second upper dry film pattern 60′ and the second lower dry film pattern 70′ with copper by any one of methods such as a CVD method, a PVD method such as a sputtering method, a subtractive method, an additive method using electroless copper plating or electro copper plating, an SAP, an MSAP, and the like.

Then, when the second upper dry film pattern 60′ and the second lower dry film pattern 70′ are delaminated and removed, the first circuit 40 connected to the first pillar 22 and the second pillar 42 are formed in an upward direction of the first insulating layer 120, and the first dummy circuit layer 50 connected to the first dummy pillar 32 and the second dummy pillar 52 are formed in a downward direction of the first dummy insulating layer 130, as shown in FIG. 2F.

Thereafter, as shown in FIG. 2G, an upper second insulating layer 140 and a second dummy insulating layer 150 each burying the second pillar 42 and the second dummy pillar 52 therein are formed.

The upper second insulating layer 140 and the second dummy insulating layer 150 are formed by compressing insulating films in a form of an unhardened film to an upper surface of the first insulating layer 120 and a lower surface of the first dummy insulating layer 130, respectively, using, for example, a laminator to bury the second pillar 42 and the second dummy pillar 52 therein, respectively.

In this case, in order to prevent damage during a compression process, the upper second insulating layer 140 and the second dummy insulating layer 150 may be formed to have thicknesses thicker than a total height of the first circuit layer 40 and the second pillar 42 and a total height of the first dummy circuit layer 50 and the second dummy pillar 52, respectively.

After the upper second insulating layer 140 and the second dummy insulating layer 150 are formed, routing is performed on the carrier substrate 10 to separate an upper coreless printed circuit precursor including a second upper copper foil 12-2 and a lower coreless printed circuit precursor including a second lower copper foil 13-2 from each other as shown in FIG. 2H.

In this case, the upper coreless printed circuit precursor and the lower coreless printed circuit precursor may be more easily separated by a release layer provided in advance between a first upper copper foil 12-1 and the second upper copper foil 12-2 or between a first lower copper foil 13-1 and the second lower copper foil 13-2.

A plurality of insulating layers including the circuit layer and the pillar are laminated on the upper coreless printed circuit precursor and the lower coreless printed circuit precursor, respectively, that are separated from each other as described above, thereby making it possible to manufacture a multilayer type coreless substrate.

In order to describe this process, the subsequent process will be described with reference to an upper coreless substrate structure including the second pillar 42. Further, the subsequent process to be described below may be equally applied to a lower coreless substrate structure including the second dummy pillar 52.

For the separated upper coreless substrate structure, a polishing cutting process is performed on the first insulating layer 120 and the upper second insulating layer 140 to remove the second upper copper foil 12-2 and expose a lower surface of the first pillar 22 and an upper surface of the second pillar 42, as shown in FIG. 21.

Here, the polishing cutting process of the first insulating layer 120 and the upper second insulating layer 140 may be performed using a belt-sander, an end-mill, or a ceramic buff or be performed by a chemical mechanical polishing (CMP) process, or the like.

Next, as shown in FIG. 2J, a third circuit layer 70 and a fourth pillar 72 are sequentially formed on a lower surface of the first insulating layer 120 exposing the first pillar 22 and a second circuit layer 60 and a third pillar 62 are sequentially formed on an upper surface of the upper second insulating layer 140 exposing the second pillar 42.

More specifically, dry films (not shown) are laminated on the lower surface of the first insulating layer 120 and the upper surface of the upper second insulating layer 140 and then subjected to exposing and developing processes to form a dry film pattern having a plurality of opening parts.

Then, the dry film pattern is filled with copper by any one of methods such as a CVD method, a PVD method such as a sputtering method, a subtractive method, an additive method using electroless copper plating or electro copper plating, an SAP, an MSAP, and the like, and then delaminated to form the third circuit layer 70 and the second circuit layer 60 the lower surface of the first insulating layer 120 and the upper surface of the upper second insulating layer 140, respective.

Next, a dry film pattern for forming a fourth pillar and a dry film pattern for forming a third pillar are formed on the lower surface of the first insulating layer 120 on which the third circuit layer 70 is disposed and the upper surface of the second insulating layer 160 on which the second circuit layer 60 is disposed.

The dry film pattern for forming a fourth pillar and the dry film pattern for forming a third pillar are filled with copper by any one of methods such as a CVD method, a PVD method such as a sputtering method, a subtractive method, an additive method using electroless copper plating or electro copper plating, an SAP, an MSAP, and the like, and then delaminated to form a third pillar 62 connected to the second circuit layer 60 and a fourth pillar 72 connected to the third circuit layer 70.

After the third pillar 62 and the fourth pillar 72 are formed, an upper third insulating layer 170 and a lower second insulating layer 160 each burying the third pillar 62 and the fourth pillar 72 therein are formed.

The upper third insulating layer 170 and the low second insulating layer 160 may be formed by compressing insulating films in a form of an unhardened film to the third pillar 62 and the fourth pillar 72, respectively, using a laminator and then performing the above-mentioned polishing cutting process, similar to the method of forming the upper second insulating layer 140.

In this case, in order to prevent damage during a compression process, the upper third insulating layer 170 and the lower second insulating layer 160 may be formed to have thicknesses thicker than heights of the third pillar 62 and the fourth pillar 72, respectively.

Thereafter, as shown in FIG. 2L, a top circuit layer 90 and a bottom circuit layer 80 are formed on the upper third insulating layer 170 and the lower second insulating layer 160 each exposing an upper surface of the third pillar 62 and a lower surface of the fourth pillar 72 by a polishing cutting process. Here, the circuit layer 90 and the bottom circuit layer 80 may be formed by filling dry film patterns with copper by any one of methods such as a CVD method, a PVD method such as a sputtering method, a subtractive method, an additive method using electroless copper plating or electro copper plating, an SAP, an MSAP, and the like, similar to the method of forming the circuit layers described above.

After the top circuit layer 90 and the bottom circuit layer 80 are formed, a first surface treating film 91 or a second surface treating film 92 is formed on the top circuit layer 90 and the bottom circuit layer 80.

The first surface treating film 91 may be any one of an OSP treating film, a black oxide film, and a brown oxide film, instead of the SR according to the prior art. Here, the OSP treating film is divided into an organic solvent type OSP treating film and a water soluble type OSP treating film, wherein the organic solvent type OSP treating film may be formed on a surface of the bottom circuit layer 80 or top circuit layer 90 by a roll coating method, a spray coating method, or the like, and the water soluble type OSP treating film may be formed by a dipping method. In addition, the black oxide film or the brown oxide film may be formed by oxidizing the top circuit layer 90 and the bottom circuit layer 80 made of copper.

Further, the second surface treating film 92 may be a film made of a metal material having high electrical conductivity, for example, a gold plating film, an electro gold plating film, an electroless gold plating film, or an ENIG plating film.

Particularly, the ENIG plating film may be formed by plating nickel by an electroless plating process and then plating immersion gold.

These first and second surface treating films 91 and 92 are not limited to the above-mentioned example, but may be an HASL layer or other surface treating layer.

With the method of manufacturing a multilayer type coreless substrate according to the first preferred embodiment of the present invention as described above, the coreless substrate including five circuit layers that are electrically connected to each other by the plurality of pillars is easily manufactured using the carrier substrate 10 and the dry film patterns, thereby making it possible to solve problems associated with a processing time and a manufacturing cost generated at the time of forming the vias using laser according to the prior art.

Particularly, with the method of manufacturing a multilayer type coreless substrate according to the first preferred embodiment of the present invention, the carrier substrate 10 and the dry film pattern are used, thereby making it possible to mass-produce the multilayer type coreless substrate without causing warpage.

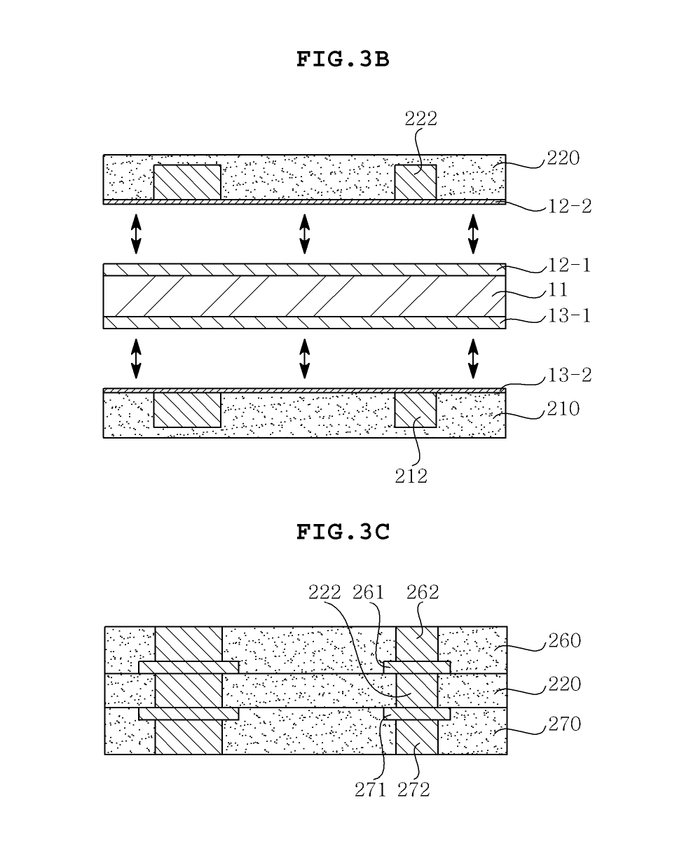

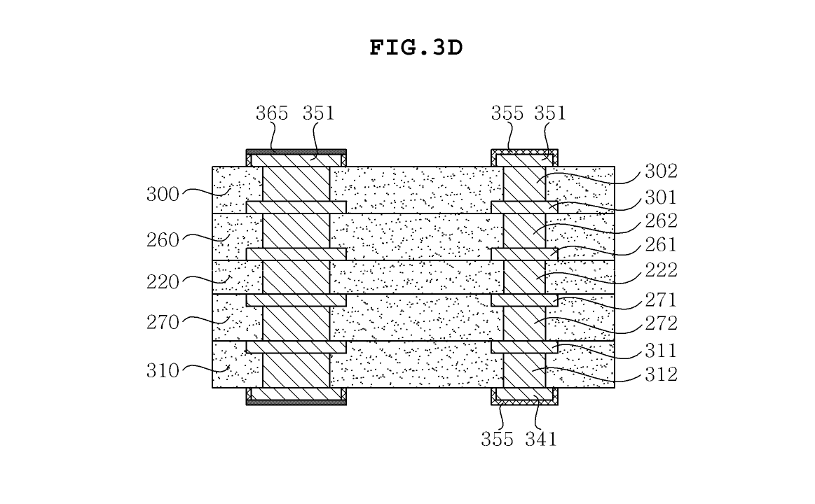

Hereinafter, a method of manufacturing a multilayer type coreless substrate according to a second preferred embodiment of the present invention will be described with reference to FIGS. 3A to 3D. FIGS. 3A to 3D are process views sequentially showing a method of manufacturing a multilayer type coreless substrate according to the second preferred embodiment of the present invention.

Here, as the method of manufacturing a multilayer type coreless substrate according to the second preferred embodiment of the present invention, a method of manufacturing a multilayer type coreless substrate having even numbered circuit layers such as six circuit layers 351, 301, 261, 271, 311, and 341 will be described. Therefore, a description of portions similar to those of the method of manufacturing a multilayer type coreless substrate according to the first preferred embodiment of the present invention in the method of manufacturing a multilayer type coreless substrate according to the second preferred embodiment of the present invention will be omitted.

In the method of manufacturing a multilayer type coreless substrate according to the second preferred embodiment of the present invention, a first insulating layer 220 burying a first pillar 222 therein and a first dummy insulating layer 210 burying a first dummy pillar 212 therein are first formed on upper and lower surfaces of a carrier substrate 10, respectively, as shown in FIG. 3A.

Then, routing is performed on the carrier substrate 10 to separate an upper coreless printed circuit precursor including a second copper foil 12-2 and a lower coreless printed circuit precursor including a second lower copper foil 13-2 based on an insulating plate 11, as shown in FIG. 3B.

Each of the upper coreless printed circuit precursor and the lower coreless printed circuit precursor that are separated from each other as described above, which is a precursor having a structure of an insulating layer including only a pillar without a circuit layer, may be manufactured as a multilayer type coreless substrate.

Then, a polishing cutting process for removing the second upper coil foil 12-2 is performed on the upper coreless printed circuit precursor. Both surfaces of the first insulating layer 220 may be planarized by the polishing cutting process. Here, the first insulating layer 220 serves as a core in the subsequent process, such that a plurality of circuit layers and pillars may be provided symmetrically to each other based on the first insulating layer 120 in a vertical direction.

Next, a first upper circuit layer 261 and a first lower circuit layer 271 are formed symmetrically to each other on both surfaces of the first pillar 222, respectively, as the subsequent process for the first insulating layer 220 exposing the first pillar 22 on both surfaces thereof. This process may also be equally performed on a lower coreless printed circuit structure.

A second upper pillar 262 and a second lower pillar 272 are formed by forming dry film patterns on the first upper circuit layer 261 and the first lower circuit layer 271, respectively, and filling these dry film patterns with copper by any one of methods such as a CVD method, a PVD method such as a sputtering method, a subtractive method, an additive method using electroless copper plating or electro copper plating, an SAP, an MSAP, and the like, respectively.

Thereafter, a second upper insulating layer 260 and a second lower insulating layer 270 each burying the second upper pillar 262 and the second lower pillar 272 therein are formed.

Then, as shown in FIG. 3C, a polishing cutting process is performed on each of the second upper insulating layer 260 and the second lower insulating layer 270 so as to expose each of the second upper pillar 262 and the second lower pillar 272.

A second upper circuit layer 301 and a second lower circuit layer 311 are formed on an upper surface of the second upper insulating layer 260 and a lower surface of the second lower insulating layer 270 polished and cut as described above, respectively, using a dry film pattern.

The above-mentioned process is repeatedly performed, thereby making it possible to form the multilayer type coreless substrate according to the second preferred embodiment of the present invention in which six circuit layers 351, 301, 261, 271, 311, and 341 including a top circuit layer 351 and a bottom circuit layer 341 having a first surface treating film 355 or a second surface treating surface 365 and four other insulating layers 260, 270, 300, and 310 are disposed symmetrically to each other based on the first insulating layer 220, as shown in FIG. 3D.

Therefore, with the method of manufacturing a multilayer type coreless substrate according to the second preferred embodiment of the present invention, the carrier substrate 10 and the dry film patterns are used to form the coreless printed circuit precursors having a laminated structure on directions of both surfaces of the carrier substrate 10, thereby making it possible to mass-produce the multilayer type coreless substrate and thus improve efficiency in producing the multilayer type coreless substrate.

As set forth above, with the multilayer type coreless substrate according to the preferred embodiment of the present invention, the structure in which the plurality of insulating layers are laminated and the plurality of pillars for electrical connection between the laminated insulating layers are easily implemented, thereby making it possible to reduce a manufacturing cost and improve integration of circuits.

In addition, with the method of manufacturing a multilayer type coreless substrate according to the preferred embodiment of the present invention, the coreless substrate in which the circuit layers electrically connected to each other by the plurality of pillars are laminated is easily manufactured using the carrier substrate and the dry film patterns, thereby making it possible to solve problems associated with a processing time and a manufacturing cost generated at the time of forming the vias using laser according to the prior art.

Further, with the method of manufacturing a multilayer type coreless substrate according to the preferred embodiment of the present invention, the carrier substrate and the dry film patterns are used, thereby making it possible to reduce a lead time and improve productivity of the multilayer type coreless substrate.

Moreover, with the method of manufacturing a multilayer type coreless substrate according to the preferred embodiment of the present invention, it is possible to improve electrical performance of the multilayer type coreless substrate.

Further, with the method of manufacturing a multilayer type coreless substrate according to the preferred embodiment of the present invention, the carrier substrate and the dry film patterns are used, thereby making it possible to mass-produce the multilayer type coreless substrate without causing warpage.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A multilayer type coreless substrate comprising:
a first insulating layer including at least one first pillar;
a plurality of insulating layers each laminated in directions of both surfaces of the first insulating layer and each including at least one circuit layer and at least one other pillar connected to the circuit layer; and
a plurality of outermost circuit layers each contacting pillars included in outermost insulating layers among the plurality of insulating layers and disposed on outer surfaces of the outermost insulating layers,
wherein the circuit layers and other pillars formed on the directions of both surfaces of the first insulating layer, respectively, are disposed symmetrically to each other based on the first insulating layer.

2. The multilayer type coreless substrate as set forth in claim 1, wherein the circuit layers and other pillars are sequentially laminated in directions of both surfaces based on the first pillar of the first insulating layer, respectively, and are disposed symmetrically to each other based on the first pillar.

3. The multilayer type coreless substrate as set forth in claim 1, wherein the outermost circuit layer includes a first or second surface treating film formed thereon.

4. The multilayer type coreless substrate as set forth in claim 3, wherein the first surface treating film is any one of an organic solderability preservative (OSP) treating film, a black oxide film, and a brown oxide film, instead of a solder resist (SR).

5. The multilayer type coreless substrate as set forth in claim 3, wherein the second surface treating film is any one of a gold plating film, an electro gold plating film, an electroless gold plating film, and an electroless nickel immersion gold (ENIG) plating film.

6. A method of manufacturing a multilayer type coreless substrate, the method comprising:
(A) preparing a carrier substrate including at least one copper foil formed on one surface or both surfaces of an insulating surface;
(B) forming a coreless printed circuit precursor on one surface or both surfaces of the carrier substrate;
(C) separating the carrier substrate;
(D) performing a polishing cutting process on the coreless printed circuit precursor; and
(E) laminating a plurality of other insulating layers on an outer surface of the coreless printed circuit precursor, the plurality of other insulating layers sequentially including other circuit layers and other pillars.

7. The method as set forth in claim 6, further comprising:
(F) forming outermost circuit layers at outermost insulating layers among other insulating layers; and
(G) forming a first or second surface treating film on the outermost circuit layers.

8. The method as set forth in claim 7, wherein the first surface treating film is any one of an OSP treating film, a black oxide film, and a brown oxide film, instead of an SR, and
the second surface treating film is any one of a gold plating film, an electro gold plating film, an electroless gold plating film, and an ENIG plating film.

9. The method as set forth in claim 6, wherein step (B) includes:
(B-1) forming a plurality of first pillars by filling a first dry film pattern disposed on one surface or both surfaces of the carrier substrate with copper;
(B-2) delaminating the first dry film pattern;
(B-3) forming a first insulating layer on one surface or both surfaces of the carrier substrate so as to bury the first pillars therein;
(B-4) performing a polishing cutting process on the first insulating layer so as to expose the first pillars;
(B-5) forming a dry film pattern for forming a first circuit layer on an outer surface of the first insulating layer exposing the first pillars;
(B-6) forming the first circuit layer by filling the dry film pattern for forming the first circuit layer with copper and delaminating the dry film pattern for forming the first circuit layer;
(B-7) forming a second dry film pattern on the outer surface of the first insulating layer including the first circuit layer;
(B-8) forming second pillars connected to the first circuit layer by filling the second dry film pattern with copper and delaminating the second dry film pattern; and
(B-9) forming a second insulating layer so as to bury the second pillars therein.

10. The method as set forth in claim 9, wherein in steps (B-1), (B-6), and (B-8), the copper is filled by any one of a chemical vapor deposition (CVD) method, a physical vapor deposition (PVD) method, a subtractive method, an additive method using electroless copper plating or electro copper plating, a semi-additive process (SAP), and a modified semi-additive process (MSAP).

11. The method as set forth in claim 9, wherein in steps (B-1), (B-6), and (B-8), the copper is filled by a sputtering method.

12. The method as set forth in claim 6, wherein step (B) includes:
(B-1) forming a plurality of first pillars by filling a first dry film pattern disposed on one surface or both surfaces of the carrier substrate with copper;
(B-2) delaminating the first dry film pattern; and
(B-3) forming a first insulating layer on one surface or both surfaces of the carrier substrate so as to bury the first pillars therein.

13. The method as set forth in claim 12, wherein in step (B-1), the copper is filled by any one of a CVD method, a PVD method, a subtractive method, an additive method using electroless copper plating or electro copper plating, an SAP, and an MSAP.

14. The method as set forth in claim 12, wherein in step (B-1), the copper is filled by a sputtering method.

15. The method as set forth in claim 6, wherein in step (C), the carrier substrate includes an insulating plate; at least two copper foils laminated on one surface or both surfaces of the insulating plate; and a release layer disposed between the copper foils and is routed and separated using the release layer.

16. The method as set forth in claim 6, wherein step (D) is performed by using any one of a belt-sander, an end-mill, or a ceramic buff, and a chemical mechanical polishing (CMP) process.

17. The method as set forth in claim 6, wherein step (E) includes:
(E-1) forming other circuit layers on the outer surface;
(E-2) forming dry film patterns for forming other pillars on the outer surface including other circuit layers formed thereon;
(E-3) forming other pillars connected to other circuit layers by filling the dry film patterns for forming other pillars with copper;
(E-4) delaminating the dry film patterns for forming other pillars;
(E-5) laminating other insulating layers so as to bury other pillars; and
(E-6) polishing and cutting other insulating layers so as to expose other pillars, and
steps (E-1) to (E-6) are repeatedly performed.

18. The method as set forth in claim 17, wherein in step (E-3), the copper is filled by any one of a CVD method, a PVD method, a subtractive method, an additive method using electroless copper plating or electro copper plating, an SAP, and an MSAP.

19. The method as set forth in claim 17, wherein in step (E-3), the copper is filled by a sputtering method.

20. The method as set forth in claim 17, wherein step (E-6) is performed by using any one of a belt-sander, an end-mill, or a ceramic buff, and a CMP process.
